(19) United States
(12) Patent Application Publication
(10) Pub. No.: US 2025/0038412 A1
(43) Pub. Date: Jan. 30, 2025

(54) ANTENNA PACKAGE

(71) Applicant: MEDIATEK INC., Hsinchu City (TW)

(72) Inventors: Nai-Chen LIU, Hsinchu City (TW); Shih-Huang YEH, Hsinchu City (TW); Chung-Hsin CHIANG, Hsinchu City (TW); Wun-Jian LIN, Hsinchu City (TW)

(21) Appl. No.: 18/547,211

(22) PCT Filed: Apr. 23, 2023
(86) PCT No.: PCT/CN2023/089973

§ 371 Date: Aug. 21, 2023

Related U.S. Application Data
(60) Provisional application No. 63/338,916, filed on May 6, 2022.

(51) Int. Cl. H01Q 9/04; H01Q 1/22; H01Q 9/06; H01Q 13/10

(52) U.S. Cl. CPC H01Q 9/0407; H01Q 1/2283; H01Q 9/065; H01Q 13/106

(57) ABSTRACT

A semiconductor package is provided. The semiconductor package includes a first passive component module, a first antenna module, a first conductive structure and a second conductive structure. The first passive component module has a top surface, a bottom surface and a first side surface between the top surface and the bottom surface. The passive component module has a first size. The first antenna module is separated from the first passive component module and stacked on the top surface of the first passive component module. The antenna module has a second size. The first conductive structure is in contact with the top surface of the first passive component module and electrically connected to the first antenna module. The second conductive structure is in contact with the bottom surface of the first passive component module.

### CROSS REFERENCE TO RELATED APPLICATIONS

This application claims the benefit of U.S. Provisional Application No. 63/338,916, filed May 6, 2022, the entirety of which is incorporated by reference herein.

### BACKGROUND OF THE INVENTION

### Field of the Invention

The present invention relates to an antenna package, and, in particular, to an antenna package that includes discrete antenna modules and passive component modules.

### Description of the Related Art

Antennas are essential components of all modern electronic devices that require radio-frequency functionality, such as smartphones, tablet computers, and notebook computers. As communication standards evolve to provide faster data transfer rates and higher throughput, the demands placed on antennas are becoming more challenging. Moreover, antennas need to be compact in size, since modern electronic devices need to be slim, lightweight, and portable, and these devices have limited space available for an antenna. Accordingly, antennas need to have a high bandwidth-to-volume ratio representing bandwidth per unit volume (measured in, e.g., Hz/(mm³)). In order to improve communication with high-end smartphone applications, an antenna module having enhanced performance and a small size is desirable.

### BRIEF SUMMARY OF THE INVENTION

An embodiment of the present invention provides an antenna package. The semiconductor package includes a first passive component module, a first antenna module, a first conductive structure and a second conductive structure. The first passive component module has a top surface, a bottom surface and a first side surface between the top surface and the bottom surface, wherein the passive component module has a first size. The first antenna module is separated from the first passive component module and stacked on the top surface of the first passive component module, wherein the antenna module has a second size. The first conductive structure is in contact with the top surface of the first passive component module and electrically connected to the first antenna module. The second conductive structure is in contact with the bottom surface of the first passive component module.

An embodiment of the present invention provides an antenna package. The semiconductor package includes first number of passive component modules each having a first pad close to a top surface and a second pad close to a bottom surface; a second number of antenna modules separated from the first number of passive component modules, wherein each of the second number of antenna modules has a third pad connected to at least one of the first pads; first conductive structures directly connected to the first pads and connected to the third pads; and second conductive structures directly connected to the second pads.

In addition, an embodiment of the present invention provides an antenna package. The semiconductor package includes a first individual passive component module, a first individual antenna module, a second individual antenna module, a first conductive structure and a second conductive structure. The first individual antenna module is stacked on the top surface of the first passive component module, wherein the first individual antenna module is operated in a first frequency band. The first individual antenna module is stacked on the top surface of the first passive component module, wherein the first individual antenna module is operated in a first frequency band. The first conductive structure is in contact with the top surface of the first individual passive component module and electrically connected to the first individual antenna module. The first conductive structure is in contact with the top surface of the first individual passive component module and electrically connected to the first individual antenna module.

### BRIEF DESCRIPTION OF THE DRAWINGS

The present invention can be more fully understood by reading the subsequent detailed description and examples with references made to the accompanying drawings, wherein:

FIG. 1 is a cross-sectional view of an antenna package in accordance with some embodiments of the disclosure;

FIGS. 2A and 2B are cross-sectional views of an antenna package in accordance with some embodiments of the disclosure, showing various embodiments of conductive structures connected to a passive component module, an antenna module and a conductive module;

FIGS. 3A, 3B, 3C, 3D, 3E and 3F are cross-sectional views of an antenna package in accordance with some embodiments of the disclosure, showing the antenna package composed of the passive component module, the antenna module and the conductive module with different sizes;

FIGS. 4A, 4B, 4C, 4D, 4E and 4F are cross-sectional views of an antenna package in accordance with some embodiments of the disclosure, showing various embodiments of the antenna package in which the antenna module and the conductive module with different shapes;

FIGS. 5A and 5B are cross-sectional views of an antenna package in accordance with some embodiments of the disclosure, showing various embodiments of the antenna package in which the passive component module and the antenna module have array arrangements;

FIGS. 6A and 6B are cross-sectional views of an antenna package in accordance with some embodiments of the disclosure, showing various embodiments of the antenna package in which the passive component module and the antenna module have array arrangements;

FIGS. 7A, 7B. 7C and 7D are cross-sectional views of an antenna package in accordance with some embodiments of the disclosure, showing various embodiments of the antenna package in which the passive component module and the antenna module have array arrangements;

FIG. 8 are cross-sectional views of an antenna package in accordance with some embodiments of the disclosure, showing some embodiments of the antenna package in which the passive component module and the antenna module have array arrangements; and

FIGS. 9A, 9B, 9C. 9D, 9E, 9F, 9G and 9H are cross-sectional views of an antenna package in accordance with some embodiments of the disclosure, showing various embodiments of the antenna package in which the passive component module and the antenna module have array arrangements.

### DETAILED DESCRIPTION OF THE INVENTION

The following description is made for the purpose of illustrating the general principles of the invention and should not be taken in a limiting sense. The scope of the invention is best determined by reference to the appended claims.

Embodiments provide an antenna package composed of at least one discrete passive component module, at least one discrete antenna module and at least one discrete conductive module. The discrete passive component modules, the antenna modules and the conductive modules are fabricated separately with optimized fabrication process, materials, sizes and numbers and improves fabrication yield. Compared with the conventional antenna package integrated antennas and passive components in a single module, the substrate area for the passive components and the fabrication cost can be reduced. In addition, the antenna performance can be improved and the impedance design flexibility can be increased.

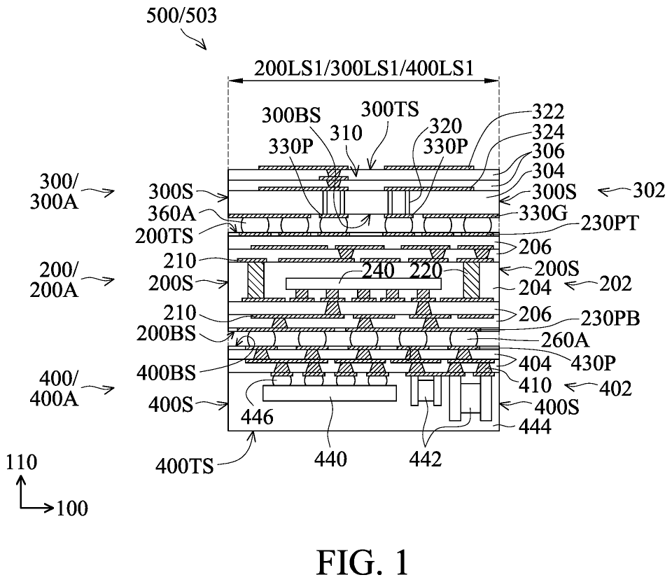

FIG. 1 is a cross-sectional view of an antenna package 500 in accordance with some embodiments of the disclosure. For illustration of the reference directions labeled in the figures, the direction 100 is defined as the lateral direction of the antenna package 500, and the direction 110 is defined as the vertical direction of the antenna package 500. The direction 100 is substantially perpendicular to the direction 110.

As shown in FIG. 1, the antenna package 500 includes a passive component module 200 (comprising passive component modules 200A. 200B. 200A1-200A4 in the following figures), an antenna module 300 (comprising antenna modules 300A. 300A1-300A5, 300A1-1 to 300A3-1, 300A1-2 to 300A3-2, 300B. 300B1, 300B2, 300B-1, 300B-2 and 300C in the following figures), a conductive module 400 (comprising conductive modules 400A, 400B and 400C in the following figures) and conductive structures 260A and 360A.

In some embodiments, the passive component module 200 has a top surface 200TS and a bottom surface 200BS and opposite side surfaces 200S adjacent to and between the top surface 200TS and the bottom surface 200BS. In some embodiments, the passive component module 200 may include a substrate 202 and one or more passive components 240.

In some embodiments, the substrate 202 includes multi-layered package substrate including a dielectric layer 204 and dielectric layers 206 stacked on opposite surfaces of the dielectric layer 204. In addition, the top surface of the topmost dielectric layer 204 and the bottom surface of the lowermost dielectric layer 204 may also serve as the top surface 200TS and the bottom surface 200BS of the passive component module 200. The dielectric layers 204 and 206 may made by same or different materials and having same or different thicknesses. In some embodiments, the substrate 202 includes a core substrate and/or a coreless substrate. For example, the substrate 202 may include a core substrate having dielectric layers 204 and 206 stacked on opposite sides of the core substrate. For example, the substrate 202 may include a coreless substrate having dielectric layers 204 and 206 stacked on one side of the coreless substrate. In some embodiments, the substrate 202 and the dielectric layers 204 and 206 are made of a material including an organic material or an inorganic material, such as FR4 material. FR5 material, bismaleimide triazine (BT) resin material, glass, ceramic, molding compound, liquid crystal polymer, glass cloth based material, epoxy resin, ferrite, silicon, another applicable material or a combination thereof.

In some embodiments, the substrate 202 includes electrical routings 210 composed of conductive layers and vias (not shown) formed in the substrate 202 for electrical connections between the passive component 240 inside the passive component module 200 and the antenna module 300 external to the passive component module 200.

The passive component 240 is disposed inside the substrate 202 and electrically connected to the electrical routings 210. For example, the passive component 240 may be disposed inside the dielectric layer 204. The passive component 240 may also be disposed between the dielectric layers 202. In some embodiments, the passive component 240 comprises a resistor, an inductor, a capacitor, or a filter. In some embodiments, the passive component module 200 may include one or more passive circuits (not shown) formed by the conductive layers and vias of the electrical routings 210 and the dielectric layers of the substrate 202. The substrate 202 and the passive circuit formed in the substrate 202 may be implemented as the passive component module 200. Therefore, the passive component 240 may be omitted.

In some embodiments, the passive component module 200 further includes pads 230PT and 230PB disposed close to the top surface 200TS and the bottom surface 200BS. Therefore, the top surfaces of the pads 230PT may form a portion of the top surface 200TS. The bottom surfaces of the pads 230PB may form a portion of the bottom surface 200BS. The pads 230PT and 230PB are electrically connected to the electrical routings 210 in the dielectric layers 202 close to the top surface 200TS and the bottom surface 200BS of the passive component module 200. In some embodiments, the passive component module 200 further includes conductive via 220 passing through the dielectric layer 204 and electrically connected to the electrical routings 210 in the dielectric layers 202 close to the top surface 200TS and the bottom surface 200BS of the passive component module 200. The passive component 240 may be electrically connected to the pads 230PT by the electrical routings 210 close to the bottom surface 200BS, the conductive via 220 and the electrical routings 210 close to the top surface 200TS.

As shown in FIG. 1, the conductive structures 260A of the antenna package 500 are formed on and in contact with the bottom surface 200BS of the passive component module 200 and electrically connected to the electrical routings 210. In some embodiments, the conductive structure 260A includes a solder ball, solder paste, a conductive pillar, a through via (TV), or a coupling pad, for example.

In some embodiments, the passive component module 200 has a size 200LS in the cross-sectional view as shown in FIG. 1. In some embodiments, the size 200LS of the passive component module 200 in the cross-sectional view may refer to the lateral size such as the length and width along the direction 100 (the lateral direction). For example, the size 200LS may be a dimension between the opposite side surfaces 200S of the passive component module 200.

In some embodiments, the passive component module 200 is an individual module separated from the antenna module 300 and the conductive module 400. The passive component module 200 includes a single kind of the electronic component such as the passive component 240. That is to say, the passive component module 200 does not include other kinds of electronic components excepting the passive component 240. For example, the passive component module 200 is fabricated without any antenna. RFIC (radio frequency integrated circuit). PMIC (power management integrated circuit), surface mount devices (SMDs) or other kinds of electronic components disposed therein. In some embodiments, the passive component module 200 is manufactured by integrated circuit (IC) (such as complementary metal-oxide-semiconductor, CMOS), substrate, printed circuit board, flexible printed circuit board, or low-temperature co-fired ceramics processes. It is noted that the structure and fabrication processes of the passive component module 200 are not limited to the disclosed embodiments.

As shown in FIG. 1, the antenna module 300 is separated from the passive component module 200 and stacked on the top surface 200TS of the passive component module 200. The antenna module 300 has a top surface 300TS and a bottom surface 300BS and opposite side surfaces 300S adjacent to and between the top surface 300TS and the bottom surface 300BS. In some embodiments, the antenna module 300 includes a substrate 302, one or more antenna 322 and 324 and a grounding layer 330G.

In some embodiments, the substrate 302 includes multi-layered package substrate including a dielectric layer 304 and dielectric layers 306 stacked on the dielectric layer 304. In addition, the top surface of the topmost dielectric layer 306 and the bottom surface of the lowermost dielectric layer 304 may also serve as the top surface 300TS and the bottom surface 300BS of the antenna module 300. The dielectric layers 304 and 306 may be made by same or different materials and having same or different thicknesses. In some embodiments, the substrate 302 includes a core substrate and/or a coreless substrate. For example, the substrate 302 may include a core substrate having dielectric layers 304 and 306 stacked on opposite sides of the core substrate. For example, the substrate 302 may include a coreless substrate having dielectric layers 304 and 306 stacked on one side of the coreless substrate. In some embodiments, the substrate 302 and the dielectric layers 304 and 306 are made of a material including an organic material or an inorganic material, such as FR4 material. FR5 material, bismaleimide triazine (BT) resin material, glass, ceramic, molding compound, liquid crystal polymer, glass cloth based material, epoxy resin, ferrite, silicon, another applicable material or a combination thereof.

The antennas 322 are formed on the top surface 300TS of the antenna module 300. In addition, the antennas 324 may be optionally in the formed in the dielectric layers 306 below the top surface 300TS of the antenna module 300. In some embodiments, the antennas 322 and 324 are separated from each other and periodically arranged as an array along the direction 100. The antenna 322 may cover a portion of the top surface 300TS of the antenna module 300. In some embodiments, the antennas 322 and 324 are broadside antennas including patch antennas, dipole antennas, and slot antennas, which means the antennas 322 and 324 may radiate signals alone the direction 110. In some embodiments, the antennas 322 and 324 are end-fire antennas, which means the antennas 322 and 324 may radiate signals alone the direction 110 or the direction perpendicular to the directions 110 and 100 simultaneously. In some embodiments, the antennas 322 and 324 may be a dual-band or multi-band antenna which can be operated at least in a first frequency band and a second frequency band that is different from the first frequency band. For example, the first frequency band has a first frequency range and the second frequency band has a second frequency range that is higher than the first range. For example, the first frequency band is a low frequency band between 24.25-29.5 GHZ, and the second frequency band is a high frequency band between 37-43.5 GHZ. 47.2-48.2 GHZ or/and 57-64 GHz.

In some embodiments, the substrate 302 includes electrical routings 310 composed of conductive layers and vias (not shown) formed in the substrate 302 and electrically connected to the antennas 322 and 324.

In some embodiments, the antenna module 300 further includes pads 330P disposed on the bottom surface 300BS. In some embodiments, the pads 330P including feeding pads are electrically connected to the electrical routings 310 in the dielectric layers 306 close to the top surface 300TS of the antenna module 300.

In some embodiments, the antenna module 300 further includes grounding layers 330G disposed on the bottom surface 300BS. In addition, the grounding layer 330G may have openings (not shown) for the corresponding pads 330P disposed therein and thus it could prevent the pads 330P from contacting physical material of the grounding layer 330G. As shown in FIG. 1, the grounding layer 330G is disposed below the antennas 322 and 324. In some embodiments, the grounding layer 330G may be also formed between the dielectric layers 304 and 306 and separated from the antennas 322 and 324. In addition, the grounding layer 330G is formed inside the substrate 302 and is not exposed from the side surface 300S of the antenna module 300. In some embodiments, the grounding layer 330G is exposed from the side surface 300S of the antenna module 300. In some embodiments, the grounding layer 330G is disposed on the bottom surface 300BS of the substrate 302. In some embodiments, the grounding layer 330G is isolated from the antennas 322 and 324. In some embodiments, the grounding layer 330G is connected to the antennas 322 and 324, which depends on antenna types or antenna design requirements. In some embodiments, the pads 330P and the grounding layer 330G could be formed in, for example, the same layer. In addition, the pads 330P and the grounding layer 330G may be made of a metal including, for example, aluminum, copper, gold, silver, iron or a combination thereof.

In some embodiments, the antenna module 300 further includes conductive via 320 passing through the dielectric layer 304 and electrically connected to the electrical routings 310 and the pads 330P. Therefore, the antennas 322 and 324 may be electrically connected to the pads 330P by the electrical routings 310 and the conductive via 320. In some embodiments, the conductive via 320 could be omitted, and the signal transmitted by the passive component module 200 and/or conductive module 400 could be coupled to the antennas 322 and 324 by using technique of slot-coupled feed.

In some embodiments, the antenna module 300 has a size 300LS in the cross-sectional view as shown in FIG. 1. In some embodiments, the size 300LS of the antenna module 300 in the cross-sectional view may refer to the lateral size such as the length and width along the direction 100 (the lateral direction). For example, the size 300LS may be a dimension between the opposite side surfaces 300S of the antenna module 300. In some embodiments, the size 300LS of the antenna module 300 is the same as or different from the size 200LS of the passive component module 200.

In some embodiments, the antenna module 300 is an individual module separated from the passive component module 200 and the conductive module 400. In addition, the antenna module 300 only includes single kind of the electrical element such as the antenna 320. That is to say, the antenna module 300 does not include other kinds of electronic components excepting the antenna 320. For example, the antenna module 300 is fabricated without any passive component disposed therein. In some embodiments, the antenna module 300 is manufactured by integrated circuit (IC) (such as complementary metal-oxide-semiconductor. CMOS), substrate, printed circuit board, flexible printed circuit board, or low-temperature co-fired ceramics processes. It is noted that the structure and fabrication processes of the antenna module 300 are not limited to the disclosed embodiments.

As shown in FIG. 1, the conductive structures 360A are formed on the bottom surface 300BS of the antenna module 300. The conductive structures 360A are electrically connected to the electrical routings 310 by the pads 330P and the grounding layer 330G of the antenna module 300. In addition, the conductive structures 360A are electrically connected to and in contact with (directly connected to) a portion of top surface 200TS of the passive component module 200 (i.e., the top surfaces of the pads 230PT). The conductive structures 360A are directly connected to the pads 230PT of the passive component module 200 and connected to the pads 330P of the antenna module 300. The pads 330P of the antenna module 300 are electrically connected to the pads 230PT of the passive component module 200. In some embodiments, the conductive structure 360A includes a solder ball, solder paste, a conductive pillar, a through via (TV), or a coupling pad, for example.

As shown in FIG. 1, the conductive module 400 is separated from the antenna module 300 and the passive component module 200. The conductive module 400 is stacked on the bottom surface 200BS of the passive component module 200 along the direction 110. In addition, the conductive module 400 is electrically connected to the passive component 200 by the conductive structures 260A. The conductive module 400 is electrically connected to the antenna module 300 by the passive component 200 and the conductive structures 260A and 360A. The conductive module 400 has a top surface 400TS and a bottom surface 400BS and opposite side surfaces 400S adjacent to and between the top surface 400TS and the bottom surface 400BS.

In some embodiments, the conductive module 400 may be a semiconductor package, for example, a surface-mount technology (SMT) package. In some embodiments, the conductive module 400 may be a printed circuit board, for example, a mainboard of a mobile device. In some embodiments, the conductive module 400, for example, a surface-mount technology (SMT) package, includes a substrate 402, electronic components 440 and 442, a molding compound 444 and conductive structures 446, as shown in FIG. 1. In addition, the conductive module 400 is mounted on the passive component module 200 by the conductive structures 260A.

The substrate 402 is disposed between the bottom surface 400BS of the conductive module 400 and the electronic components 440 and 442. In some embodiments, the substrate 402 is a multi-layered package substrate including the stacked dielectric layers 404 made by same or different materials. In some embodiments, the substrate 402 includes a core substrate and/or a coreless substrate. For example, the substrate 402 may include a core substrate having the dielectric layers 404 stacked on opposite sides of the core substrate. For example, the substrate 402 may include a coreless substrate having dielectric layers 404 stacked on one side of the coreless substrate. In some embodiments, the substrate 402 and the dielectric layers 404 are made of a material including an organic material or an inorganic material, such as FR4 material. FR5 material, bismaleimide triazine (BT) resin material, glass, ceramic, molding compound, liquid crystal polymer, glass cloth based material, epoxy resin, ferrite, silicon, another applicable material or a combination thereof. In some embodiments, the substrates 202, 302 and 402 are made of the same or different materials. In some embodiments, the substrates 202, 302 and 402 are fabricated by separated processes. In some embodiments, the substrates 202, 302 and 402 may be not simultaneously formed.

The substrate 402 may include electrical routings 410 composed of conductive layers and vias (not shown) formed in the substrate 402 for electrical connections between the electronic components 440 and 442 and the conductive structures 260A and between the electronic components 440 and 442.

In some embodiments, the conductive module 400 further includes pads 430P disposed close to the bottom surface 400BS. Therefore, the bottom surfaces of the pads bottom may form a portion of the bottom surface 400BS. The pads 430P are electrically connected to the electrical routings 410 in the dielectric layers 402 close to the bottom surface 400BS of the conductive module 400. In addition, the pads 430P are electrically connected to and in contact with the conductive structures 260A. In other words, the conductive structures 260A are directly connected to the pads 230PB of the passive component module 200 and the pads 430P of the conductive module 400.

The electronic components 440 and 442 are disposed on the substrate 402 and electrically connected to the substrate 402 by conductive structures 446. In addition, the electronic components 440 and 442 of the conductive module 400 and the conductive structures 260A are disposed on opposite surfaces of the substrate 402. The electronic components 440 and 442 may be electrically connected to the passive component module 200 by the pads 430P and the conductive structures 260A. In addition, the electronic components 440 and 442 of the conductive module 400 may be electrically connected to the antenna module 300 by the conductive structures 260A, the passive component module 200 and the conductive structures 360A. In some embodiments, the conductive structures 260A and 360A and 446 may comprise the same or similar materials and structures. In some embodiments, the size of the conductive structures 260A and 360A may be greater than the size of the conductive structures 446. In some embodiment, the electronic components 440 and 442 include a radio frequency integrated circuit (RFIC), a power management integrated circuit (PMIC) or a combination thereof. In some embodiment, the electronic components 440 and 442 include electronic components other than passive components.

As shown in FIG. 1, the molding compound 444 of the conductive module 400 may partially or fully covers the substrate 402 and encapsulates the electronic components 440 and 442. In addition, side surfaces (not shown) of the molding compound 444 may form a portion of the side surfaces 400S of the conductive module 400. Furthermore, the top surface (not shown) of the molding compound 444 may form the top surface 400TS of the conductive module 400. In some embodiments, the molding compound 444 is made of a material including, for example, a Novolac-based resin, an epoxy-based resin, a silicone-based resin, or another suitable encapsulant. The molding compound 444 may include suitable fillers, such as powdered SiO2. The molding compound 444 can be applied using any of a number of molding techniques, such as compression molding, injection molding, or transfer molding.

In some embodiments, the conductive module 400 has a size 400LS in the cross-sectional view as shown in FIG. 1. In some embodiments, the size 400LS of the conductive module 400 in the cross-sectional view may refer to the lateral size such as the length and width along the direction 100 (the lateral direction). For example, the size 400LS may be a dimension between the opposite side surfaces 400S of the conductive module 400. In some embodiments, the size 400LS of the conductive module 400 is the same as or different from the size 200LS of the passive component module 200 and/or the size 300LS of the antenna module 300. In some embodiments, the conductive module 400 is manufactured by integrated circuit (IC) (such as complementary metal-oxide-semiconductor. CMOS), substrate, printed circuit board, flexible printed circuit board, or low-temperature co-fired ceramics processes. It is noted that the structure and fabrication processes of the conductive module 400 are not limited to the disclosed embodiments. In some embodiments, the passive component module 200, the antenna module 300 and the conductive module 400 in the same antenna package 500 may be individually fabricated using the same or different fabrication processes depending on requirements.

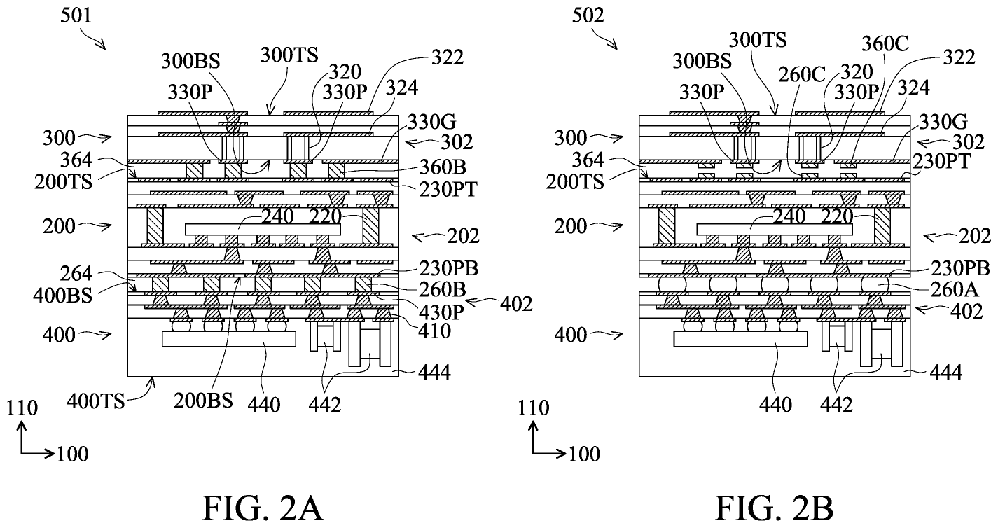

FIGS. 2A and 2B are cross-sectional views of antenna packages 501 and 502 in accordance with some embodiments of the disclosure, showing various embodiments of conductive structures 260A. 260B. 260C. 360B and 360C connected to the passive component module 200, the antenna module 300 and the conductive module 400. Elements of the embodiments hereinafter, that are the same or similar as those previously described with reference to FIG. 1, are not repeated for brevity. It is appreciated that although some features are shown in some embodiments but not in other embodiments, these features may (or may not) exist in other embodiments whenever possible. For example, although each of the illustrated example embodiments shows specific arrangements of the conductive structures connected to the passive component module 200, the antenna module 300 and the conductive module 400, any other combinations of arrangements of the conductive structures connected to the passive component module 200, the antenna module 300 and the conductive module 400 may also be used whenever applicable. In addition, other combinations of the conductive structures 260A-260C and 360A-360C may be implemented in the antenna packages 501 and 502 whenever applicable.

As shown in FIG. 2A, the difference between the antenna packages 500 and 501 is that the antenna package 501 includes conductive structures 260B and 360B and molding compounds 264 and 364. The molding compound 264 fills the space (not shown) between the bottom surface 200BS of the passive component module 200 and the bottom surface 400BS of the conductive module 400. The molding compound 364 fills the space (not shown) between the top surface 200TS of the passive component module 200 and the bottom surface 300BS of the antenna module 300. In some embodiments, the conductive structures 260B and 360B include through vias (TVs). The conductive structures 260B pass through the molding compound 264. Opposite ends of the conductive structures 260B are in contact with the pads 230PB of the passive component module 200 and the pads 430P of the conductive module 400. The conductive structures 360B pass through the molding compound 364. Opposite ends of the conductive structures 360B are in contact with the pads 230PT of the passive component module 200 and the pads 330P (or the grounding layers 330G) of the antenna module 300.

As shown in FIG. 2B, the difference between the antenna packages 500 and 502 is that the antenna package 502 includes conductive structures 260C and 360C and the molding compound 364. The molding compound 364 fills the space (not shown) between the top surface 200TS of the passive component module 200 and the bottom surface 300BS of the antenna module 300. In some embodiments, the conductive structures 260C and 360C include coupling pads. The conductive structures 260C and 360C are disposed on the passive component module 200 and the antenna module 300 and separated from each other by the molding compound 364. More specifically, the conductive structures 260C are in contact with the pads 230PT of the passive component module 200 and separated from the pads 330P of the antenna module 300. The conductive structures 360C are in contact with the pads 330P (or the grounding layers 330G) of the antenna module 300 and separated from the pads 230PT of the passive component module 200. The conductive structures 260C substantially align with the corresponding conductive structures 360C along the direction 110. In some embodiments, the conductive structures 260C and 360C (such as coupling pads) may be electrically connected to each other by electrically coupling. Therefore, the conductive structures 260C and 360C may be configured to receive and/or transmit signals wirelessly. For example, the signals from the passive component module 200 and/or the conductive module 400 may transmit to the antenna module 300 wirelessly by the conductive structures 260C and 360C. Alternatively, the signals received by the antennas 322 and/or the antennas 324 may transmit to the passive component module 200 and/or the conductive module 400 wirelessly by the conductive structures 260C and 360C. In some embodiments, the pads 230PT of the passive component module 200 and the pads 330P of the antenna module 300 may serve as the coupling pads to be electrically connected to each other by electrically coupling. Therefore, the conductive structures 260C and 360C may be omitted.

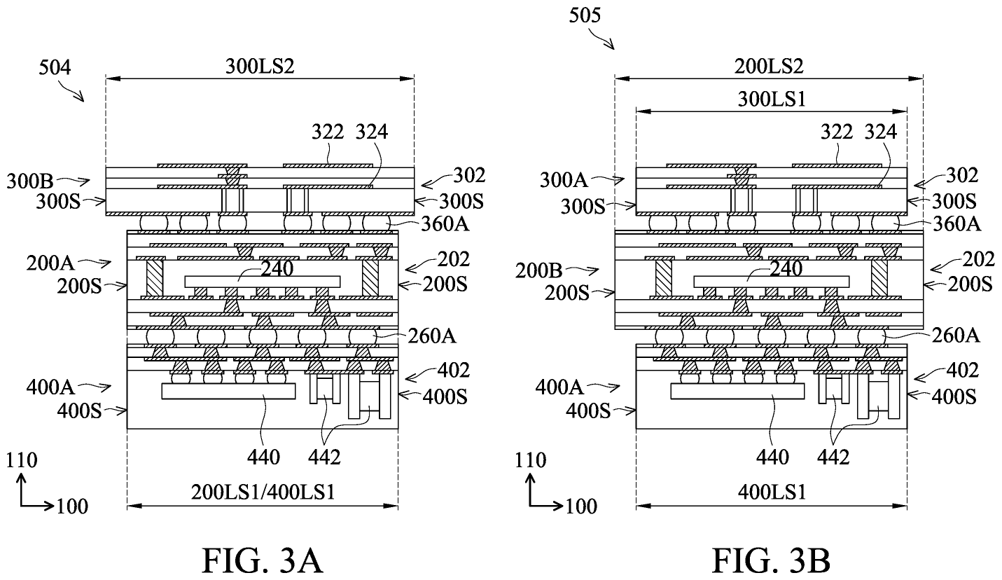

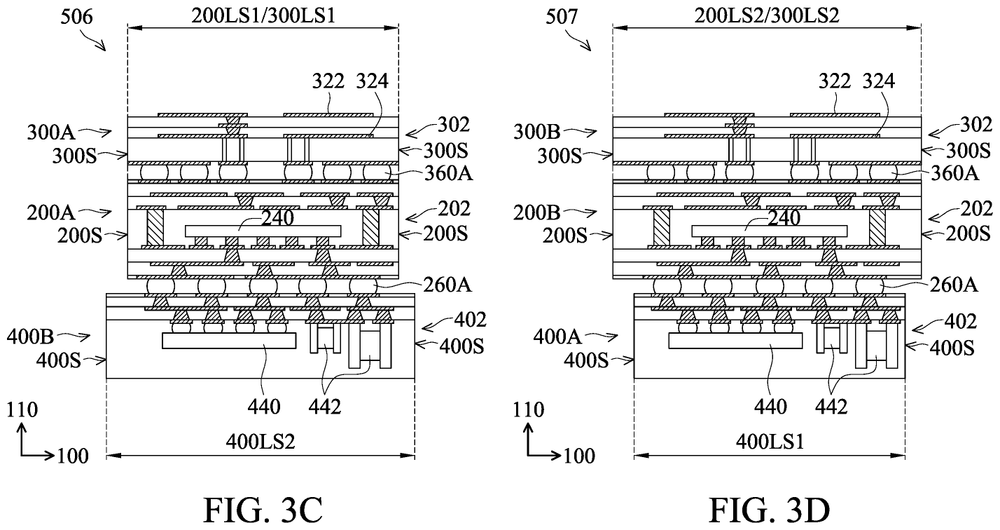

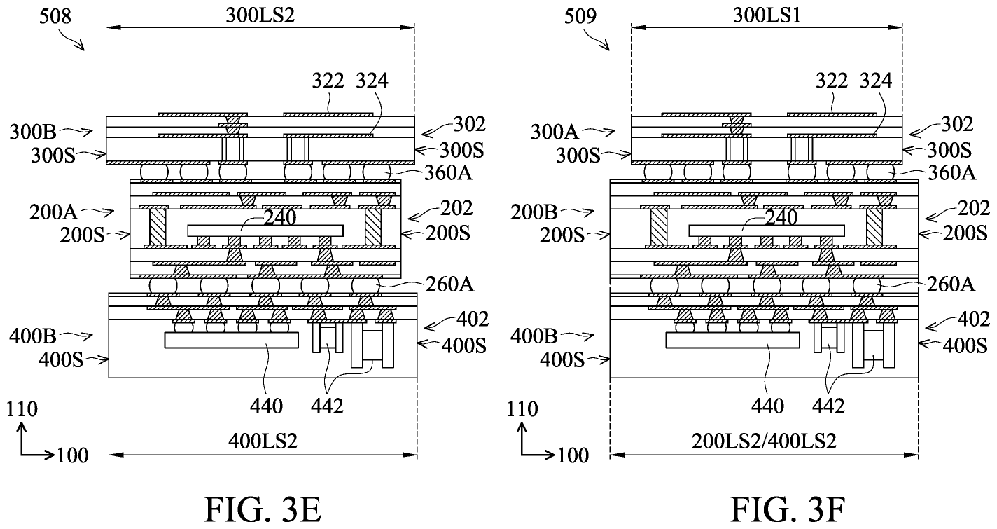

FIG. 1 also shows a cross-sectional view of an antenna package 503 in accordance with some embodiments of the disclosure in which a passive component module 200A, an antenna module 300A and a conductive module 400A having the same size. FIGS. 3A, 3B, 3C, 3D, 3E and 3F are cross-sectional views of antenna packages 504, 505, 506, 507, 508 and 509 in accordance with some embodiments of the disclosure, showing the antenna package composed of the passive component module, the antenna module and the conductive module with different sizes. Elements of the embodiments hereinafter, that are the same or similar as those previously described with reference to FIGS. 1, 2A and 2B, are not repeated for brevity. It is appreciated that although some features are shown in some embodiments but not in other embodiments, these features may (or may not) exist in other embodiments whenever possible. For example, although each of the illustrated example embodiments shows specific arrangements of the passive component module, the antenna module and the conductive module with different sizes, any other combinations of arrangements of the antenna package composed of the passive component module, the antenna module and the conductive module with different sizes may also be used whenever applicable. In addition, other combinations of the conductive structures 260A-260C and 360A-360C may be implemented in the antenna packages 504-509 whenever applicable.

As shown in FIG. 1, in the antenna package 503, the passive component module 200A has a size 200LS1, the antenna module 300A has a size 300LS1 and the conductive module 400A has a size 400LS1. In some embodiments, the size 400LS1 of the conductive module 400A is the same as the size 200LS1 of the passive component module 200A and the size 300LS1 of the antenna module 300A. In other words, the passive component module 200A, the antenna module 300A and the conductive module 400A fully overlap each other along the direction 110. In addition, the side surfaces 400S of the conductive module 400A may align with the corresponding side surfaces 200S of the passive component module 200A and the corresponding side surfaces 300S of the antenna module 300A.

As shown in FIG. 3A, the difference between the antenna packages 503 and 504 is that the antenna package 504 includes an antenna module 300B having a size 300LS2. In some embodiments, the size 300LS2 of the antenna module 300B is greater than the size 200LS1 of the passive component module 200A and the size 400LS1 of the conductive module 400A. In other words, the passive component module 200A and the conductive module 400A partially overlap the antenna module 300B along the direction 110. In addition, the side surfaces 300S of the antenna module 300B may be located outside the side surfaces 200S of the passive component module 200A and the side surfaces 400S of the conductive module 400A along the direction 110.

As shown in FIG. 3B, the difference between the antenna packages 503 and 505 is that the antenna package 505 includes a passive component module 200B having a size 200LS2. In some embodiments, the size 200LS2 of the passive component module 200B is greater than the size 300LS1 of the antenna module 300A and the size 400LS1 of the conductive module 400A. In other words, the antenna module 300A and the conductive module 400A partially overlap the passive component module 200B along the direction 110. In addition, the side surfaces 200S of the passive component module 200B may be located outside the side surfaces 300S of the antenna module 300A and the side surfaces 400S of the conductive module 400A along the direction 110.

As shown in FIG. 3C, the difference between the antenna packages 503 and 506 is that the antenna package 506 includes a conductive module 400B a size 400LS2. In some embodiments, the size 400LS2 of the conductive module 400B is greater than the size 200LS1 of the passive component module 200A and the size 300LS1 of the antenna module 300A. In other words, the antenna module 300A and the passive component module 200A partially overlap the conductive module 400B along the direction 110. In addition, the side surfaces 400S of the conductive module 400B may be located outside the side surfaces 200S of the passive component module 200A and the side surfaces 300S of the antenna module 300A along the direction 110.

As shown in FIG. 3D, the difference between the antenna packages 503 and 507 is that the antenna package 507 includes the antenna module 300B having the size 300LS2 and the passive component module 200B having the size 200LS2. In some embodiments, the size 300LS2 of the antenna module 300B is the same as or different from the size 200LS2 of the passive component module 200B. In some embodiments, the size 300LS2 of the antenna module 300B and the size 200LS2 of the passive component module 200B are greater than the size 400LS1 of the conductive module 400A. In other words, the conductive module 400A partially overlaps the antenna module 300B and the passive component module 200B along the direction 110. In addition, the side surfaces 200S of the passive component module 200B and the side surfaces 300S of the antenna module 300B may be located outside the side surfaces 400S of the conductive module 400A along the direction 110.

As shown in FIG. 3E, the difference between the antenna packages 503 and 508 is that the antenna package 508 includes the antenna module 300B having the size 300LS2 and the conductive module 400B the size 400LS2. In some embodiments, the size 300LS2 of the antenna module 300B is the same as or different from the size 400LS2 of the conductive module 400B. In some embodiments, the size 300LS2 of the antenna module 300B and the size 400LS2 of the conductive module 400B are greater than the size 200LS1 of the passive component module 200A. In other words, the passive component module 200A partially overlaps the antenna module 300B and the conductive module 400B along the direction 110. In addition, the side surfaces 300S of the antenna module 300B and the side surfaces 400S of the conductive module 400B may be located outside the side surfaces 200S of the passive component module 200A along the direction 110.

As shown in FIG. 3F, the difference between the antenna packages 503 and 509 is that the antenna package 509 includes the passive component module 200B having the size 200LS2 and the conductive module 400B the size 400LS2. In some embodiments, the size 200LS2 of the passive component module 200B is the same as or different from the size 400LS2 of the conductive module 400B. In some embodiments, the size 200LS2 of the passive component module 200B and the size 400LS2 of the conductive module 400B are greater than the size 300LS1 of the antenna module 300A. In other words, the antenna module 300A partially overlaps the passive component module 200B and the conductive module 400B along the direction 110. In addition, the side surfaces 200S of the passive component module 200B and the side surfaces 400S of the conductive module 400B may be located outside the side surfaces 300S of the antenna module 300A along the direction 110.

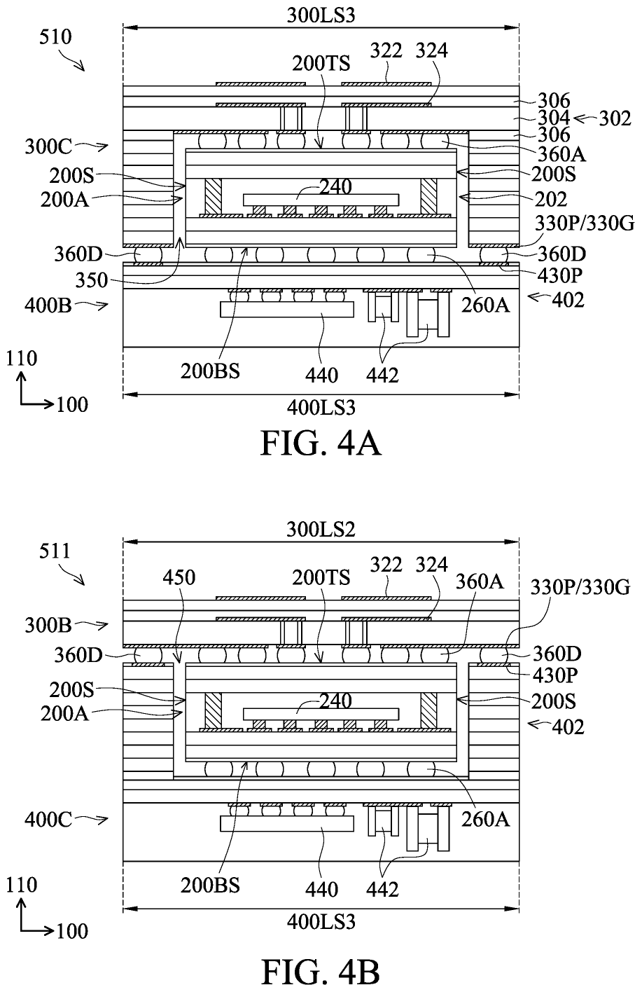

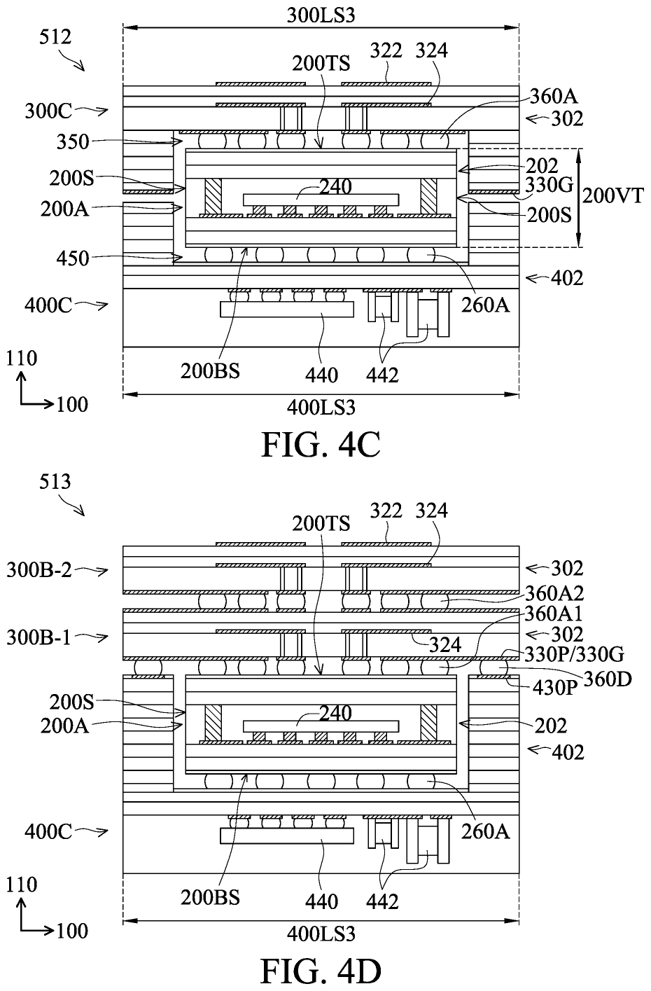

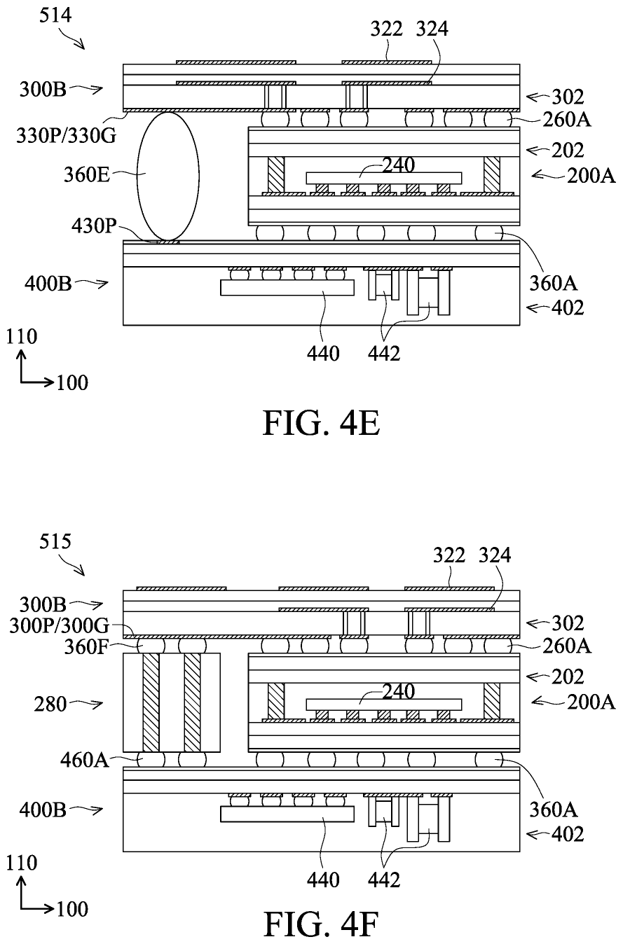

FIGS. 4A, 4B, 4C, 4D, 4E and 4F are cross-sectional views of antenna packages 510, 511, 512, 513, 514 and 515 in accordance with some embodiments of the disclosure, showing various embodiments of the antenna package in which the antenna module and the conductive module with different shapes in a cross-sectional view. Elements of the embodiments hereinafter, that are the same or similar as those previously described with reference to FIGS. 1, 2A-2B and 3A-3F, are not repeated for brevity. In addition, some features (including the dielectric layers of the substrate, the electrical routings, the pads of the antenna module, the passive component module and the conductive module) shown in FIG. 1 may be hidden in the following figures for illustration. It is appreciated that although some features are shown in some embodiments but not in other embodiments, these features may (or may not) exist in other embodiments whenever possible. For example, although each of the illustrated example embodiments shows specific arrangements of the antenna module and the conductive module having different shapes and sizes, any other combinations of arrangements of the antenna module and the conductive module having different shapes and sizes may also be used whenever applicable. In addition, other combinations of the conductive structures 260A-260C and 360A-360C may be implemented in the antenna packages 510-515 whenever applicable.

As shown in FIG. 4A, the difference between the antenna packages 503 and 510 is that the antenna package 510 includes an antenna module 300C having a size 300LS3 and the conductive module 400B. In some embodiments, the size 300LS3 of the antenna module 300C is greater than the size 200LS1 (FIG. 1) of the passive component module 200A. In some embodiments, the size 300LS3 of the antenna module 300C is greater than or equal to the size 400LS2 of the conductive module 400B. In some embodiments, the antenna module 300C is disposed over the passive component module 200A. In addition, the antenna module 300C may have a cavity 350 to accommodate the passive component module 200A. As shown in FIG. 4A, the antenna module 300C may extends from the top surface 200TS of the passive component module 200A to the side surfaces 200S of the passive component module 200A. In other words, the antenna module 300C may extend covering the adjacent top surface 200TS and side surface 200S of the passive component module 200A. In some embodiments, the antenna module 300C may have an inversed U-shape in the cross-sectional view as shown in FIG. 4A.

In some embodiments, the antenna package 510 further includes conductive structures 360D electrically connected and in contact with the pads 330P and/or the grounding layer 330G of the antenna module 300C and the pads 430P of the conductive module 400B. In addition, the conductive structures 360D may be not directly connected to the pads 230PB (FIG. 1) of the of the passive component module 200A. In some embodiments, the conductive structures 360A and 360D may comprise the same or similar materials and structures.

As shown in FIG. 4B, the difference between the antenna packages 503 and 511 is that the antenna package 511 includes a conductive module 400C having a size 400LS3 and the antenna module 300B. In some embodiments, the size 400LS3 of the conductive module 400C is greater than the size 200LS1 of the passive component module 200A. In some embodiments, the size 400LS3 of the conductive module 400C is greater than or equal to the size 300LS2 of the antenna module 300B. In some embodiments, the conductive module 400C is disposed below the passive component module 200A. In addition, the conductive module 400C may have a cavity 450 to accommodate the passive component module 200A. As shown in FIG. 4B, the conductive module 400C may extends from the bottom surface 200BS of the passive component module 200A to the side surfaces 200S of the passive component module 200A. In other words, the conductive module 400C may extend covering the adjacent bottom surface 200BS and side surface 200S of the passive component module 200A. In some embodiments, the conductive module 400C may have a U-shape in the cross-sectional view as shown in FIG. 4B.

In some embodiments, the antenna package 511 further includes the conductive structures 360D electrically connected and in contact with the pads 330P and/or the grounding layer 330G of the antenna module 300C and the pads 430P of the conductive module 400C. In addition, the conductive structures 360D may be not directly connected to the pads 230PB of the of the passive component module 200A.

As shown in FIG. 4C, the difference between the antenna packages 510, 511 and 512 is that the antenna package 512 includes the antenna module 300C having the size 300LS3 and the conductive module 400C having the size 400LS3. In some embodiments, the cavity 350 of the antenna module 300C is substantially aligned with the cavity 450 of the conductive module 400C along the direction 110 in order to collectively accommodate the passive component module 200A. Therefore, the passive component module 200A may have a thicker thickness 200VT along the direction 110.

As shown in FIG. 4D, the difference between the antenna packages 511 and 513 is that the antenna package 513 includes antenna modules 300B-1 and 300B-2 having the size 300LS2 and the conductive module 400C. In some embodiments, the antenna modules 300B-1 and 300B-2 are disposed over the passive component module 200A. The antenna module 300B-2 is stacked on the antenna module 300B-1 and electrically connected to the antenna module 300B-1 by conductive structures 360A2. In addition, the antenna module 300B-1 is stacked on the passive component module 200A and electrically connected to the passive component module 200A by the conductive structures 360A1. Furthermore, the antenna module 300B-1 is stacked on the conductive module 400C and electrically connected to the conductive module 400C by the conductive structures 360D. The antenna module 300B-2 is stacked on the antenna module 300B-1 opposite the passive component module 200A along the direction 110 substantially vertical to the top surface 200TS of the passive component module 200A. In addition, the antenna module 300B-2 is separated from the conductive structures 260A by the passive component module 200A. In addition, the antenna modules 300B-1 and 300B-2 may be operated in different frequency bands, radiation directions and/or polarizations. In some embodiments, the conductive structures 360A. 360A1, 360A2 and 360D may comprise the same or similar materials and structures.

As shown in FIG. 4E, the difference between the antenna packages 503 and 514 is that the antenna package 514 includes conductive structure 360E. The conductive structure 360E is disposed between the antenna module 300B and the conductive module 400B along the direction 110 and beside the passive component module 200A along the direction 100. The conductive structure 360E is electrically connected and in contact with the pads 330P and/or the grounding layer 330G of the antenna module 300B and the pads 430P of the conductive module 400B. In addition, the conductive structures 360E may be not directly connected to the pads 230PB of the of the passive component module 200A. In some embodiments, the dimension of the conductive structure 360E may be greater than the conductive structures 260A and 360A. In some embodiments, the conductive structures 360A. 360A1, 360A2, 360D and 360E may comprise the same or similar materials and structures. Therefore, some of the electrical routings 310 (FIG. 1) of the antenna module 300B may be provided as the additional electrical routings of the conductive module 400B.

As shown in FIG. 4F, the difference between the antenna packages 514 and 515 is that the antenna package 515 includes a through via (TV) structure 280. The TV structure 280 is disposed between the antenna module 300B and the conductive module 400B along the direction 110 and beside the passive component module 200A along the direction 100. The TV structure 280 is electrically connected to the pads 330P and/or the grounding layer 330G of the antenna module 300B by conductive structures 360F. In addition, the TV structure 280 the pads 430P of the conductive module 400B by conductive structures 460A. In addition, the TV structure 280 may be not directly connected to the pads 230PB (FIG. 1) of the of the passive component module 200A. In some embodiments, the conductive structures 360A. 360A1, 360A2, 360D. 360F and 460A may comprise the same or similar materials and structures.

In some embodiments, the TV structure 280 includes a molding compound (not shown) and through vias (TVs) (not shown) passing through the molding compound. Opposite ends of the TVs are in contact with the conductive structures 360F and 460A. Therefore, the dimension of the conductive structure 360E may be the same or similar to that of the conductive structure 360A. The dimension of the conductive structure 460A may be the same or similar to that of the conductive structure 260A.

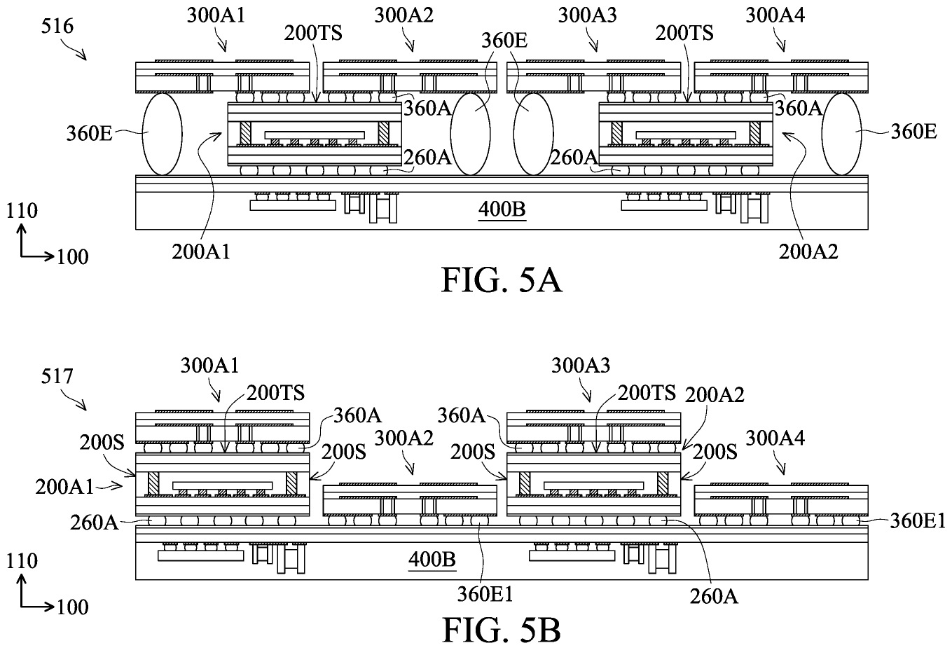

FIGS. 5A and 5B are cross-sectional views of antenna packages 516 and 517 in accordance with some embodiments of the disclosure, showing various embodiments of the antenna package in which the passive component module and the antenna module have array arrangements. Elements of the embodiments hereinafter, that are the same or similar as those previously described with reference to FIGS. 1, 2A-2B. 3A-3F and 4A-4F, are not repeated for brevity. In addition, some features (including the dielectric layers of the substrate, the electrical routings, the pads of the antenna module, the passive component module and the conductive module) shown in FIG. 1 may be hidden in the following figures for illustration. It is appreciated that although some features are shown in some embodiments but not in other embodiments, these features may (or may not) exist in other embodiments whenever possible. For example, although each of the illustrated example embodiments shows specific arrangements of the passive component module and the antenna module having array arrangements, any other combinations of arrangements of the antenna module and the passive component module and the antenna module having array arrangements may also be used whenever applicable. In addition, other combinations of the conductive structures 260A-260C and 360A-360E may be implemented in the antenna packages 516 and 517 whenever applicable.

As shown in FIG. 5A, the difference between the antenna packages 514 and 516 is that the antenna package 516 includes passive component modules 200A1 and 200A2 and antenna modules 300A1, 300A2, 300A3 and 300A4 having array arrangements. The passive component modules 200A1 and 200A2 are arranged side-by-side along the direction 100 substantially parallel to the top surfaces 200TS of the passive component modules 200A1 and 200A2. The passive component modules 200A1 and 200A2 are electrically connected to the conductive module 400B by the conductive structures 260A.

As shown in FIG. 5A, the antenna modules 300A1, 300A2, 300A3 and 300A4 are arranged side-by-side along the direction 100 substantially parallel to the top surfaces 200TS of the passive component modules 200A1 and 200A2. The antenna modules 300A1 and 300A2 are disposed on the passive component module 200A1 and separated from the conductive structures 260A by the passive component module 200A1. In addition, the antenna modules 300A1 and 300A2 are stacked on and partially overlap the top surface 200TS of the passive component module 200A1. The antenna modules 300A1 and 300A2 are electrically connected to the passive component module 200A1 by the conductive structures 360A. The antenna modules 300A3 and 300A4 are disposed on the passive component module 200A2 and separated from the conductive structures 260A by the passive component module 200A2. The antenna modules 300A3 and 300A4 are stacked on and partially overlap the top surface 200TS of the passive component module 200A2. The antenna modules 300A3 and 300A4 are electrically connected to the passive component module 200A2 by the conductive structures 360A. In addition, the antenna modules 300A1, 300A2, 300A3 and 300A4 are electrically connected to the conductive module 400B by the conductive structures 360E to provide additional electrical routings for the conductive module 400B.

In some embodiments, each of the separated passive component modules of the antenna package 516 may be connected to one or more antenna module having overlapping operating frequency range. The antenna modules having non-overlapping operating frequency range may be connected to different separated passive component modules. Compared with the conventional antenna package using a single passive component module connected to all the dual-band and/or multi-band antenna modules, the separated passive component modules may have reduced area. Therefore, the manufacturing cost can be reduced. As shown in FIG. 5A, the antenna modules 300A1 and 300A2 having overlapping operating frequency range are connected to the passive component module 200A1. The antenna modules 300A3 and 300A4 having overlapping operating frequency range are connected to the passive component module 200A2. The antenna modules 300A1, 300A2, 300A3 and 300A4 may be dual-band or multi-band antennas which can be operated at least in a first frequency band and a second frequency band that is different from the first frequency band. For example, the antenna module 300A1 may be a dual-band antenna which can be operated in the first frequency band (low frequency band) between 37-43.5 GHZ and the second frequency band (high frequency band) between 47.2-48.2 GHz. The antenna module 300A2 may be a multi-band antenna which can be operated in the first frequency band between 24.25-29.5 GHZ, the second frequency band (medium frequency band) between 37-43.5 GHZ and the third frequency band (high frequency band) between 47.2-48.2 GHz. In addition, the antenna modules 300A3 and 300A4 may be dual-band antennas which can be operated in the first frequency band (low frequency band) between 47.2-48.2 GHZ and the second frequency band (high frequency band) between 57-64 GHZ. In some embodiments, the antenna modules 300A1, 300A2, 300A3 and 300A4 of the antenna package 516 may be operated in the same frequency band with different radiated directions and/or polarizations.

As shown in FIG. 5B, the difference between the antenna packages 516 and 517 is that the antenna package 517 includes the antenna modules 300A2 and 300A4 arranged side-by-side with the passive component modules 200A1 and 200A2 along the direction 100. In other words, the antenna modules 300A2 and 300A4 are disposed on the passive component modules 200A1 and 200A2 along the direction 110 and separated from the conductive structures 260A by the passive component modules 200A1 and 200A2. In addition, the antenna modules 300A1 and 300A2 are respectively stacked on and partially overlap the top surface 200TS and the side surface 200S of the passive component module 200A1. The antenna modules 300A3 and 300A4 are 516 and 517 stacked on and partially overlap the top surface 200TS and the side surface 200S of the passive component module 200A2. The antenna modules 300A1 and 300A3 is electrically connected to the passive component modules 200A1 and 200A2 by the conductive structures 360A. The antenna modules 300A2 and 300A4 are electrically connected to the conductive module 400B by the conductive structures 360E1. In some embodiments, there is no conductive structure directly connected between the passive component modules 200A1 and 200A2 and the passive component modules 200A1 and 200A2. In some embodiments, the conductive structures 260A. 360A and 360E1 may comprise the same or similar materials and structures.

In some embodiments, the antenna module operated in a single frequency band (or high frequency band) may be directly connected to the conductive module without using the passive component module. The passive component module may have a reduced size. Therefore, the manufacturing cost can be reduced. For example, the antenna module 300A1 connected to the passive component module 200A1 and the antenna module 300A3 connected to the passive component module 200A2 may be multi-band antennas which can be operated in the first frequency band between 24.25-29.5 GHZ, the second frequency band between 37-43.5 GHZ and the third frequency band between 57-64 GHZ. In some embodiments, the antenna modules 300A1 and 300A3 of the antenna package 517 may be operated in the same frequency band with different radiated directions and/or polarizations. In addition, the antenna modules 300A2 and 300A4 directly connected to the conductive module 400B may be a single-band antenna which can be operated in the frequency band between 57-64 GHZ higher than the operation frequency band of the antenna modules 300A1 and 300A3. In some embodiments, the antenna modules 300A2 and 300A4 of the antenna package 517 may be operated in the same frequency band with different radiated directions and/or polarizations.

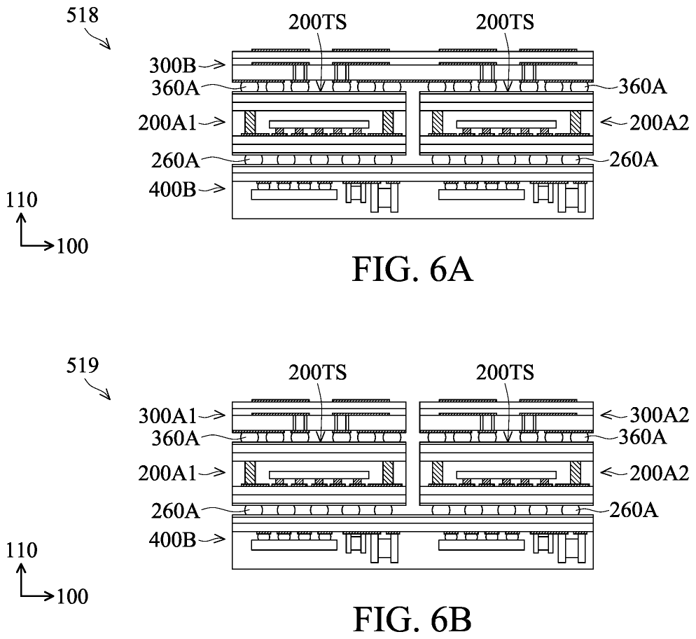

FIGS. 6A and 6B are cross-sectional views of antenna packages 518 and 519 in accordance with some embodiments of the disclosure, showing various embodiments of the antenna package in which the passive component module and the antenna module have array arrangements. Elements of the embodiments hereinafter, that are the same or similar as those previously described with reference to FIGS. 1, 2A-2B. 3A-3F. 4A-4F and 5A-5B, are not repeated for brevity. In addition, some features (including the dielectric layers of the substrate, the electrical routings, the pads of the antenna module, the passive component module and the conductive module) shown in FIG. 1 may be hidden in the following figures for illustration. It is appreciated that although some features are shown in some embodiments but not in other embodiments, these features may (or may not) exist in other embodiments whenever possible. For example, although each of the illustrated example embodiments shows specific arrangements of the passive component module and the antenna module having array arrangements, any other combinations of arrangements of the antenna module and the passive component module and the antenna module having array arrangements may also be used whenever applicable. In addition, other combinations of the conductive structures 260A-260C and 360A-360E may be implemented in the antenna packages 518 and 519 whenever applicable.

As shown in FIG. 6A, the difference between the antenna packages 503 and 518 is that the antenna package 518 includes the antenna module 300B, the passive component modules 200A1 and 200A2 and the conductive module 400B. In addition, the passive component modules 200A1 and 200A2 may have array arrangements. The passive component modules 200A1 and 200A2 are arranged side-by-side along the direction 100 substantially parallel to the top surfaces 200TS of the passive component modules 200A1 and 200A2. The passive component modules 200A1 and 200A2 are electrically connected to the conductive module 400B by the conductive structures 260A. In addition, the antenna module 300B is stacked on and overlaps the top surfaces 200TS of the passive component modules 200A1 and 200A2 along the direction 110. The antenna module 300B is electrically connected to the passive component modules 200A1 and 200A2 by the conductive structures 360A. In some embodiments, the passive component modules 200A1 and 200A2 may include different passive components formed by optimized fabrication processes. The total area of the passive component modules can be reduced, thereby reducing the manufacturing cost.

As shown in FIG. 6B, the difference between the antenna packages 503 and 519 is that the antenna package 519 includes the antenna modules 300A1 and 300A2, the passive component modules 200A1 and 200A2 and the conductive module 400B. In addition, the antenna modules 300A1 and 300A2 and the passive component modules 200A1 and 200A2 may have array arrangements. The passive component modules 200A1 and 200A2 are arranged side-by-side along the direction 100 substantially parallel to the top surfaces 200TS of the passive component modules 200A1 and 200A2. The passive component modules 200A1 and 200A2 are electrically connected to the conductive module 400B by the conductive structures 260A. In addition, the antenna modules 300A1 and 300A2 are arranged side-by-side along the direction 100. The antenna modules 300A1 and 300A2 are disposed on the passive component modules 200A1 and 200A2 and separated from the conductive structures 260A by the passive component modules 200A1 and 200A2. The antenna modules 300A1 and 300A2 are stacked on and overlap the top surfaces 200TS of the passive component modules 200A1 and 200A2 along the direction 110, respectively. The antenna modules 300A1 and 300A2 are electrically connected to the passive component modules 200A1 and 200A2 by the conductive structures 360A. In some embodiments, the antenna modules 300A1 and 300A2 may include antennas operated in different frequency bands, directions and/or polarizations or formed by different optimized fabrication processes. In some embodiments, the antenna modules 300A1 and 300A2 of the antenna package 519 may be operated in the same frequency band with different radiated directions and/or polarizations. In some embodiments, the passive component modules 200A1 and 200A2 may include different passive components formed by optimized fabrication processes. The total area of the antenna modules and the passive component modules can be reduced, thereby reducing the manufacturing cost.

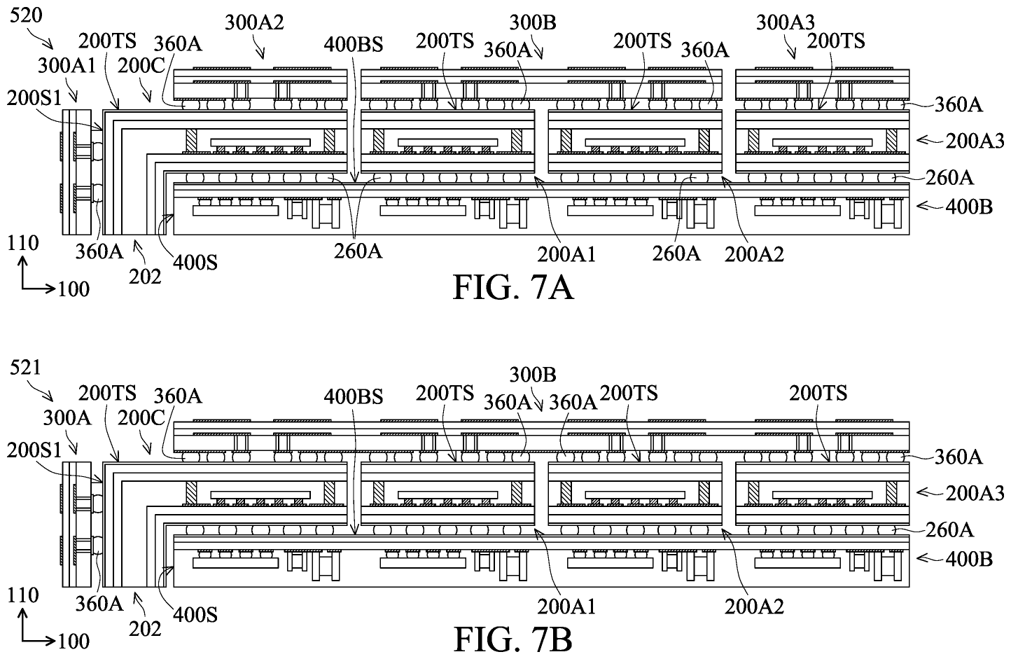

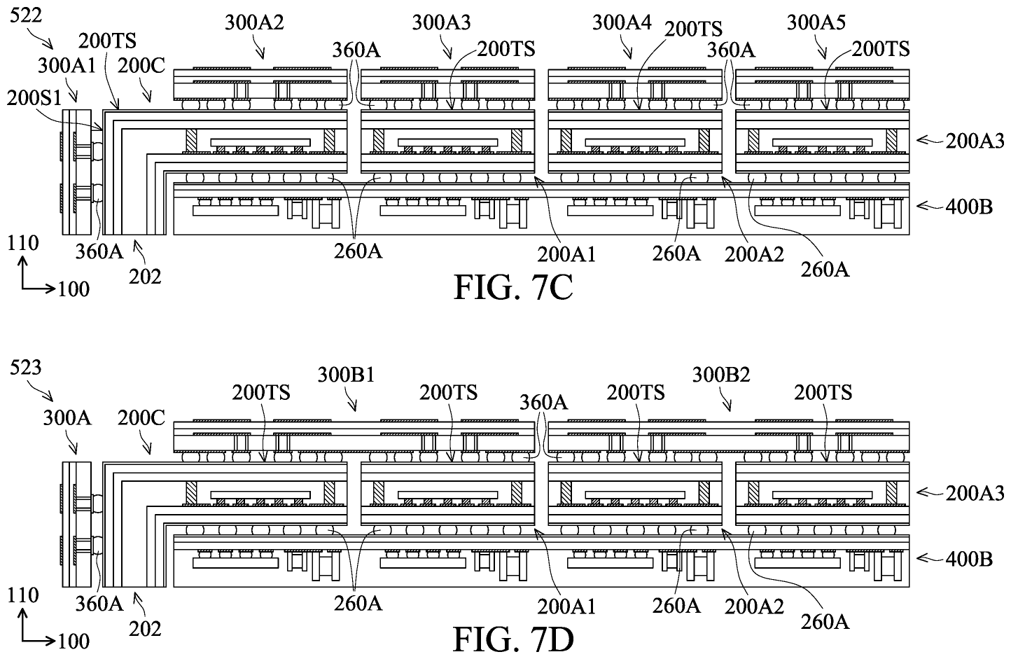

FIGS. 7A, 7B, 7C and 7D are cross-sectional views of antenna packages 520, 521, 522 and 523 in accordance with some embodiments of the disclosure, showing various embodiments of the antenna package in which the passive component module and the antenna module have array arrangements. Elements of the embodiments hereinafter, that are the same or similar as those previously described with reference to FIGS. 1, 2A-2B. 3A-3F. 4A-4F. 5A-5B and 6A-6B, are not repeated for brevity. In addition, some features (including the dielectric layers of the substrate, the electrical routings, the pads of the antenna module, the passive component module and the conductive module) shown in FIG. 1 may be hidden in the following figures for illustration. It is appreciated that although some features are shown in some embodiments but not in other embodiments, these features may (or may not) exist in other embodiments whenever possible. For example, although each of the illustrated example embodiments shows specific arrangements of the passive component module and the antenna module having array arrangements, any other combinations of arrangements of the antenna module and the passive component module and the antenna module having array arrangements may also be used whenever applicable. In addition, other combinations of the conductive structures 260A-260C and 360A-360E may be implemented in the antenna packages 520-523 whenever applicable.

As shown in FIG. 7A, the difference between the antenna packages 518, 519 and 520 is that the antenna package 520 includes the antenna modules 300A1-300A3 and 300B, the passive component modules 200A1-200A3 and 200C, and the conductive module 400B. The passive component modules 200A1, 200A2 and 200A3 are arranged side-by-side along the direction 100. The passive component modules 200A1, 200A2 and 200A3 are electrically connected to the conductive module 400B by the conductive structures 260A. In some embodiments, the passive component 200C such as a flexible printed circuit (FPC) is disposed beside the passive component module 200A1. The substrate 202 of the passive component 200C, which includes the dielectric layers 202 and 204, the electrical routings 210 and the pads 230PT (FIG. 1), may extend to cover the bottom surface 400BS and the adjacent side surface 400S of the conductive module 400B. The passive component 200C may be connected to the bottom surface 400BS of the conductive module 400B by the conductive structures 260A. In addition, the passive component 200C may be connected to the bottom surface 400BS of the conductive module 400B by adhesive (not shown).

In some embodiments, the passive component 200C extending along adjacent surfaces of the conductive module 400B may have increased area for various requirements, so a side surface 200S1 of the passive component 200C may be connected to the separated antenna modules 300A1 and 300A2. In addition, the antenna modules 300A1 and 300A2 may be dual-band antennas. For example, the antenna modules 300A1 and 300A2 can be operated in the first frequency band (low frequency band) between 37-43.5 GHZ and the second frequency band (high frequency band) between 47.2-48.2 GHZ.

In some embodiments, the antenna module 300B having the greater size 300LS2 (FIG. 3A) overlaps and is electrically connected to the passive component modules 200A1 and 200A2. In addition, the antenna module 300B may be a multi-band antenna. For example, the antenna module 300B can be operated in the first frequency band between 24.25-29.5 GHZ, the second frequency band between 37-43.5 GHZ and the third frequency band between 47.2-48.2 GHZ. The antenna module 300A3 overlaps and is electrically connected to the passive component module 200A3. In addition, the antenna module 300A3 may be a dual-band antenna. For example, the antenna module 300A3 can be operated in the first frequency band (low frequency band) between 47.2-48.2 GHz and the second frequency band (high frequency band) between 57-64 GHz. Since the passive component 200C is connected to both the antenna modules 300A1 and 300A2, the number of the conductive structures 260A connected between the passive component 200C and the conductive module 400B may be greater than the number of the conductive structures 260A connected between the passive component 200A1, 200A2 or 200A3 and the conductive module 400B. In some embodiments, the antenna modules 300A1, 300A2 and 300B of the antenna package 520 may be operated in the same frequency band with different radiated directions and/or polarizations.

As shown in FIG. 7B, the difference between the antenna packages 520 and 521 is that the antenna package 521 includes the antenna modules 300A and 300B, the passive component modules 200A1-200A3 and 200C, and the conductive module 400B. The antenna module 300B overlaps and is electrically connected to the passive component modules 200A1-200A3 and 200C. In addition, the antenna modules 300A and 300B can be disposed on the side surface 200S1 and the top surface 200TS adjacent to the side surface 200S1 of the passive component 200C. In addition, the antenna modules 300A and 300B may be dual-band antennas. For example, the antenna module 300B can be operated in the first frequency band (low frequency band) between 37-43.5 GHZ and the second frequency band (high frequency band) between 47.2-48.2 GHZ. In some embodiments, the antenna modules 300A and 300B of the antenna package 521 may be operated in the same frequency band with different radiated directions and/or polarizations.

As shown in FIG. 7C, the difference between the antenna packages 520 and 522 is that the antenna package 522 includes the antenna modules 300A1-300A5, the passive component modules 200A1-200A3 and 200C, and the conductive module 400B. The antenna modules 300A1 and 300A2 may be disposed on the side surface 200S1 and the top surface 200TS adjacent to the side surface 200S1 of the passive component 200C. In addition, the antenna modules 300A1 and 300A2 may be dual-band antennas. For example, the antenna modules 300A1 and 300A2 can be operated in the first frequency band (low frequency band) between 37-43.5 GHZ and the second frequency band (high frequency band) between 47.2-48.2 GHZ. The antenna modules 300A3, 300A4 and 300A5 may be disposed on and electrically connected to the passive component modules 200A1, 200A2 and 200A3. In addition, the antenna module 300A3 may be a multi-band antenna. For example, the antenna module 300A3 can be operated in the first frequency band (low frequency band) between 37-43.5 GHZ and the second frequency band (high frequency band) between 47.2-48.2 GHz. In addition, the antenna modules 300A1-300A5 may be dual-band or multi-band antennas. For example, the antenna modules 300A1 and 300A2 can be operated in the first frequency band (low frequency band) between 37-43.5 GHZ and the second frequency band (high frequency band) between 47.2-48.2 GHZ. The antenna module 300A can be operated in the first frequency band between 24.25-29.5 GHZ, the second frequency band between 37-43.5 GHZ and the third frequency band between 47.2-48.2 GHZ. The antenna modules 300A4 and 300A5 can be operated in the first frequency band (low frequency band) between 47.2-48.2 GHZ and the second frequency band (high frequency band) between 57-64 GHz. In some embodiments, the antenna modules 300A1-300A5 of the antenna package 522 may be operated in the same frequency band with different radiated directions and/or polarizations.

As shown in FIG. 7D, the difference between the antenna packages 520 and 523 is that the antenna package 523 includes the antenna modules 300A. 300B1 and 300B2, the passive component modules 200A1-200A3 and 200C, and the conductive module 400B. The antenna module 300B1 overlaps and is electrically connected to the passive component modules 200A1 and 200C. The antenna module 300B2 overlaps and is electrically connected to the passive component modules 200A2 and 200A3. In addition, the antenna modules 300A and 300B1 can be disposed on the side surface 200S1 and the top surface 200TS adjacent to the side surface 200S1 of the passive component 200C. In addition, the antenna modules 300A. 300B1 and 300B2 may be dual-band antennas. For example, the antenna modules 300A and 300B1 can be operated in the first frequency band (low frequency band) between 37-43.5 GHZ and the second frequency band (high frequency band) between 47.2-48.2 GHZ. The antenna module 300B2 can be operated in the first frequency band (low frequency band) between 47.2-48.2 GHZ and the second frequency band (high frequency band) between 57-64 GHZ. In some embodiments, the antenna modules 300A. 300B1 and 300B2 of the antenna package 523 may be operated in the same frequency band with different radiated directions and/or polarizations.

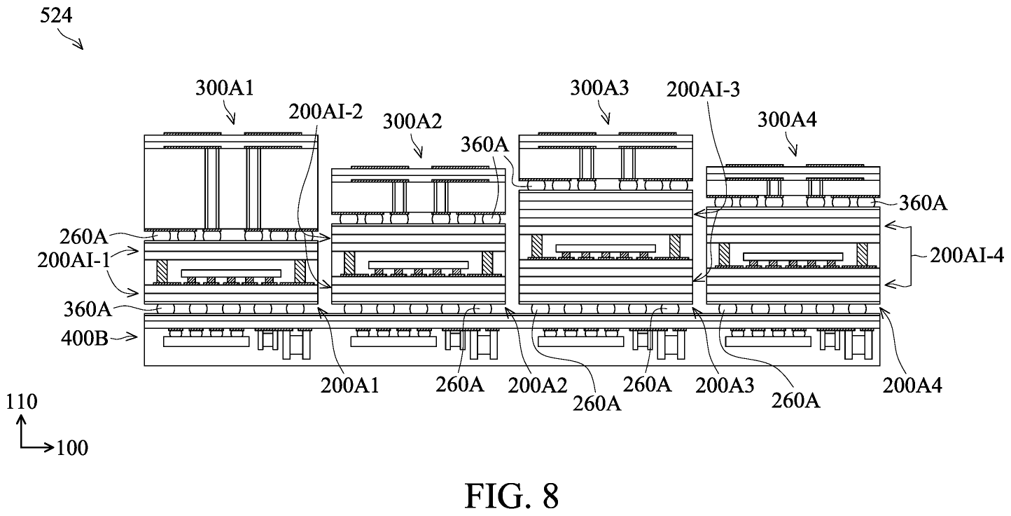

FIG. 8 is a cross-sectional view of an antenna package 524 in accordance with some embodiments of the disclosure, showing some embodiments of the antenna package in which the passive component module and the antenna module have array arrangements. Elements of the embodiments hereinafter, that are the same or similar as those previously described with reference to FIGS. 1, 2A-2B. 3A-3F. 4A-4F. 5A-5B. 6A-6B and 7A-7D, are not repeated for brevity. In addition, some features (including the dielectric layers of the substrate, the electrical routings, the pads of the antenna module, the passive component module and the conductive module) shown in FIG. 1 may be hidden in the following figures for illustration. It is appreciated that although some features are shown in some embodiments but not in other embodiments, these features may (or may not) exist in other embodiments whenever possible. For example, although each of the illustrated example embodiments shows specific arrangements of the passive component module and the antenna module having array arrangements, any other combinations of arrangements of the antenna module and the passive component module and the antenna module having array arrangements may also be used whenever applicable. In addition, other combinations of the conductive structures 260A-260C and 360A-360E may be implemented in the antenna package 524 whenever applicable.

As shown in FIG. 8, the difference between the antenna packages 519 and 524 is that the antenna package 524 includes the antenna modules 300A1, 300A2, 300A3 and 300A4, the passive component modules 200A1, 200A2, 200A3 and 200A4, and the conductive module 400B. In some embodiments, the antenna modules 300A1-300A4 operated in different frequency bands may be connected to the passive component module including interconnect structures formed of different numbers of dielectric layers. In some embodiments, the antenna module operated in a higher frequency band may be connected to the passive component module including interconnect structures formed of greater numbers of dielectric layers. For example, the antenna module 300A1 operated in a low frequency band may be connected to the passive component module 200A1 including an interconnect structure 200AI-1 formed of two dielectric layers 216. The antenna module 300A2 operated in a medium frequency band may be connected to the passive component module 200A2 including an interconnect structure 200AI-2 formed of three dielectric layers 216. The antenna module 300A4 operated in a high frequency band may be connected to the passive component module 200A4 including an interconnect structure 200AI-4 formed of four dielectric layers 216. In addition, the antenna module 300A3 operated in multiple frequency bands may be connected to the passive component module 200A3 including an interconnect structure 200AI-4 formed of six dielectric layers 216. As shown in FIG. 8, the antenna module operated in a higher frequency band may have a compact size, while the antenna module operated in a lower frequency band may a large size. In some embodiments, the antenna modules 300A1-300A4 of the antenna package 524 may be operated in the same or different frequency bands with different radiated directions and/or polarizations. It is noted that the number of the dielectric layers of the passive component modules 200A1, 200A2, 200A3 and 200A4 is not limited to the disclosed embodiments.

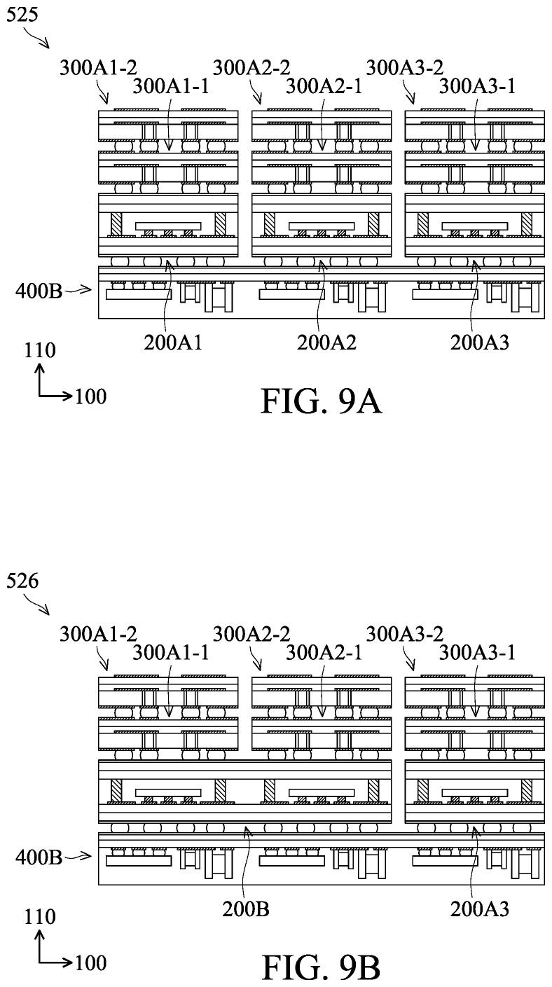

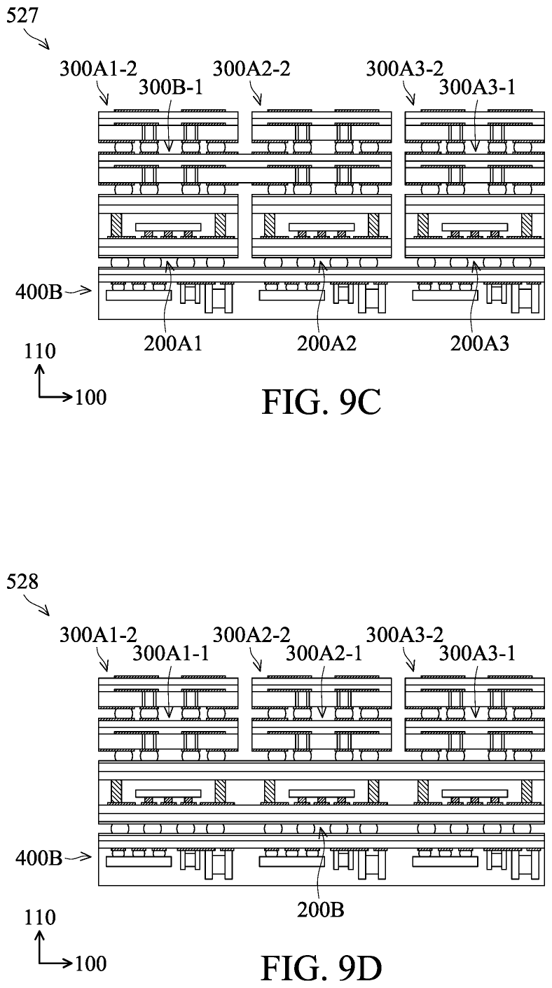

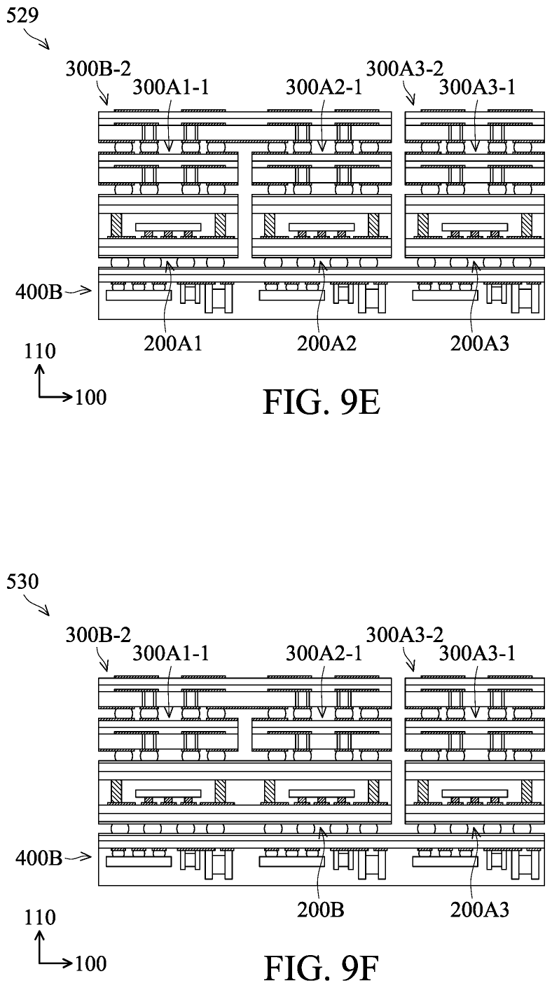

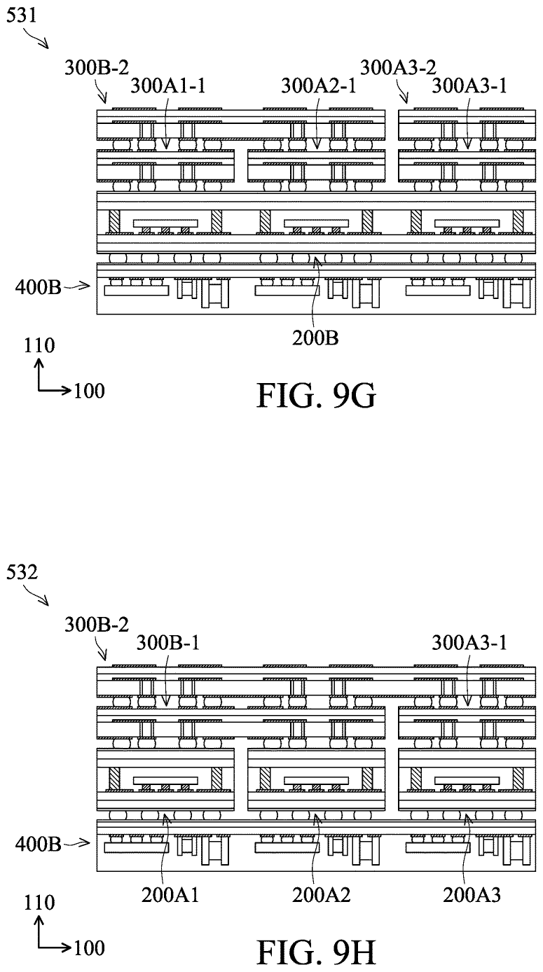

FIGS. 9A, 9B, 9C, 9D, 9E, 9F, 9G and 9H are cross-sectional views of antenna packages 525, 526, 527, 528, 529, 530, 531 and 532 in accordance with some embodiments of the disclosure, showing various embodiments of the antenna package in which the passive component modules and the antenna modules have array arrangements. In addition, some of the antenna modules have vertically stacked on top of each other. In some embodiments, the antenna packages 525, 526, 527, 528, 529, 530, 531 and 532 may provide increased design flexibility. In some embodiments, the antenna modules of the antenna packages 525, 526, 527, 528, 529, 530, 531 and 532 may be operated in the same or different frequency bands, radiation directions and/or polarizations. Elements of the embodiments hereinafter, that are the same or similar as those previously described with reference to FIGS. 1, 2A-2B. 3A-3F. 4A-4F. 5A-5B. 6A-6B. 7A-7D and 8, are not repeated for brevity. In addition, some features (including the dielectric layers of the substrate, the electrical routings, the pads of the antenna module, the passive component module and the conductive module) shown in FIG. 1 may be hidden in the following figures for illustration. It is appreciated that although some features are shown in some embodiments but not in other embodiments, these features may (or may not) exist in other embodiments whenever possible. For example, although each of the illustrated example embodiments shows specific arrangements of the passive component module and the antenna module having array arrangements, any other combinations of arrangements of the antenna module and the passive component module and the antenna module having array arrangements may also be used whenever applicable. In addition, other combinations of the conductive structures 260A-260C and 360A-360E may be implemented in the antenna packages 525-531 whenever applicable.

As shown in FIG. 9A, the difference between the antenna packages 519 and 525 is that the antenna package 525 includes the passive component modules 200A1, 200A2 and 200A3 arranged side-by-side and disposed on the conductive module 400B. Each of the passive component modules 200A1, 200A2 and 200A3 may be stacked below the antenna modules having the same size and vertically stacked each other. For example, the passive component module 200A1 may be stacked below antenna modules 300A1-1 and 300A1-2, and the antenna module 300A1-2 is vertically stacked on the antenna module 300A1-1. The passive component module 200A2 may be stacked below antenna modules 300A2-1 and 300A2-2, and the antenna module 300A2-2 is vertically stacked on the antenna module 300A2-1. The passive component module 200A3 may be stacked below antenna modules 300A3-1 and 300A3-2, and the antenna module 300A3-2 is vertically stacked on the antenna module 300A3-1.

As shown in FIG. 9B, the difference between the antenna packages 525 and 526 is that the antenna package 526 includes the passive component modules 200A3 and 200B having different sizes. The passive component module 200A3 is stacked below the antenna modules 300A3-1 and 300A3-2, and the antenna module 300A3-2 is vertically stacked on the antenna module 300A3-1. The passive component module 200B is stacked below the antenna modules 300A1-1, 300A1-2, 300A2-1 and 300A2-2. The antenna modules 300A1-1 and 300A2-1 are arranged side-by-side along the direction 100. In addition, the antenna module 300A1-2 is vertically (along the direction 110) stacked on the antenna module 300A1-1. The antenna module 300A2-2 is vertically stacked on the antenna module 300A2-1.

As shown in FIG. 9C, the difference between the antenna packages 525 and 527 is that the antenna package 527 includes the antenna modules 300B-1, 300A3-1, 300A1-2, 300A2-2 and 300A3-2 having different sizes. For example, the passive component module 200A1 and 200A2 are stacked below the antenna modules 300A1-2, 300A2-2 and 300B-1, and the antenna modules 300A1-2 and 300A2-2 are vertically stacked on the antenna module 300B-1 having a greater size (such as the size 300LS2 shown in FIG. 3A). The passive component module 200A3 may be stacked below antenna modules 300A3-1 and 300A3-2, and the antenna module 300A3-2 is vertically stacked on the antenna module 300A3-1.

As shown in FIG. 9D, the difference between the antenna packages 525 and 528 is that the antenna package 528 includes the passive component module 200B having the greater size (such as the size 200LS2 in FIG. 3B) and overlapping the antenna modules 300A1-1, 300A2-1, 300A3-1, 300A1-2, 300A2-2 and 300A3-2. For example, the passive component module 200B is stacked below the antenna modules 300A1-1, 300A2-1, 300A3-1, 300A1-2, 300A2-2 and 300A3-2. In addition, the antenna modules 300A1-2, 300A2-2 and 300A3-2 are vertically stacked on the antenna modules 300A1-1, 300A2-1 and 300A3-1, respectively.

As shown in FIG. 9E, the difference between the antenna packages 525 and 529 is that the antenna package 529 includes the antenna modules 300A1-1, 300A2-1, 300A3-1, 300B-2 and 300A3-2 having different sizes. 300A1-1, 300A2-1, 300A3-1, 300A1-2, 300A2-2 and 300A3-2. For example, the passive component modules 200A1 and 200A2 arranged side-by-side are stacked below the antenna modules 300A1-1, 300A2-1 and 300B-2. The antenna module 300B-2 having a greater size (such as the size 300LS2 shown in FIG. 3A) is vertically stacked on the antenna modules 300A1-1 and 300A2-1 arranged side-by-side.

As shown in FIG. 9F, the difference between the antenna packages 529 and 530 is that the antenna package 530 includes the passive component module 200B having the greater size (such as the size 200LS2 in FIG. 3B) and overlapping the antenna modules 300A1-1, 300A2-1 and 300B-2 having different sizes. For example, the passive component module 200B is stacked below the antenna modules 300A1-1, 300A2-1 and 300B-2. In addition, the antenna module 300B-2 having a greater size (such as the size 300LS2 shown in FIG. 3A) is vertically stacked on the antenna modules 300A1-1 and 300A2-1 arranged side-by-side.

As shown in FIG. 9G, the difference between the antenna packages 530 and 531 is that the antenna package 531 includes the passive component module 200B having the greater size (such as the size 200LS2 in FIG. 3B) and overlapping the antenna modules 300A1-1, 300A2-1, 300A3-1, 300B-2 and 300A3-2 having different sizes. For example, the passive component module 200B is stacked below the antenna modules 300A1-1, 300A2-1, 300A3-1, 300B-2 and 300A3-2. In addition, the antenna module 300B-2 having a greater size (such as the size 300LS2 shown in FIG. 3A) is vertically stacked on the antenna modules 300A1-1 and 300A2-1 arranged side-by-side. The antenna module 300A3-2 is vertically stacked on the antenna module 300A3-1.

As shown in FIG. 9H, the difference between the antenna packages 527 and 532 is that the antenna package 532 includes the antenna modules 300B-1, 300A3-1 and 300B-2 having different sizes. The topmost antenna module 300B-2 may have a greater size than the antenna module 300B-1, and the antenna modules 300B-1 may have a greater size than the antenna module 300A3-1 beside the antenna modules 300B-1. For example, the passive component module 200A1 and 200A2 are stacked below the antenna modules 300B-1 and 300B-2. The passive component module 200A3 may be stacked below antenna modules 300A3-1 and 300B-2. In addition, the antenna module 300B-2 is vertically stacked on the antenna modules 300B-1 and 300A3-1.

Embodiments provide an antenna package. The antenna package includes separated passive component modules and separated antenna modules stacked on the corresponding passive component modules. In some embodiments, the passive component module is fabricated without any antenna disposed therein. The antenna module is fabricated without any passive component disposed therein. The antenna package may separate antenna and passive components into multiple modules which can be manufactured by optimized fabrication process, materials, sizes and numbers to improve fabrication yield. Each module may be connect each other by conductive structure including conductive bumps, balls, through vias, coupling pads or other type of interconnects as RLC components to improve the antenna performance. In some embodiments, the antenna module, the passive component module and the conductive module can be implemented in different numbers and different sizes for various requirements. Compared with the conventional antenna package which integrates antennas and passive components in a single module, the non-required substrate area can be reduced. In some embodiments, the interconnections between the antenna module and the passive component module and/or between the passive component module and the conductive module can be fabricated using different metal/materials and types of interconnections cooperating with different materials of the underfill, which can be regarded as quick-assembly mmWave/Sub-THz RLC components, to reduce required area of the passive component module and increase the impedance design flexibility.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. An antenna package, comprising:
a first passive component module having a top surface, a bottom surface and a first side surface between the top surface and the bottom surface, wherein the passive component module has a first size;
a first antenna module separated from the first passive component module and stacked on the top surface of the first passive component module, wherein the antenna module has a second size;
a first conductive structure in contact with the top surface of the first passive component module and electrically connected to the first antenna module; and
a second conductive structure in contact with the bottom surface of the first passive component module.

2. (canceled)

3. The antenna package as claimed in claim 1, wherein the first antenna module extends from the top surface of the first passive component module to the first side surface of the first passive component module.

4. The antenna package as claimed in claim 1, further comprising:
a conductive module stacked on the bottom surface of the first passive component module and electrically connected to the first passive component by the second conductive structure, wherein the conductive module has a third size.

5. The antenna package as claimed in claim 4, wherein the conductive module comprises:
a substrate; and
an electronic component disposed on the substrate.

6. The antenna package as claimed in claim 4, wherein the conductive module extends from the bottom surface of the first passive component module to the first side surface of the first passive component module.

7. The antenna package as claimed in claim 4, wherein the first passive component extends to cover adjacent surfaces of the conductive module.

8. The antenna package as claimed in claim 4, further comprising:
a third conductive structure directly connected between the first antenna module and the conductive module.

9. The antenna package as claimed in claim 1, further comprising:
a second antenna module disposed on the first passive component module and separated from the second conductive structure by the first passive component module.

10. The antenna package as claimed in claim 9, wherein the first antenna module and the second antenna module are arranged side-by-side along a first direction, and the first direction is substantially parallel to the top surface of the first passive component module.

11. The antenna package as claimed in claim 9, wherein the second antenna module is stacked on the first antenna module opposite the first passive component module along a second direction, and the second direction is substantially vertical to the top surface of the first passive component module.

12. The antenna package as claimed in claim 9, wherein the second antenna module is stacked on the first side surface of the first passive component module.

13. The antenna package as claimed in claim 9, wherein the second antenna module has a fourth size, and the fourth size is different from the first size or the second size.

14. The antenna package as claimed in claim 1, further comprising:
a molding compound filling a space between the passive component module and the antenna module, wherein the first conductive structure passes through the molding compound.

15. The antenna package as claimed in claim 1, further comprising:
a molding compound filling a space between the passive component module and the antenna module; and
a fourth conductive structure in contact with the antenna module, wherein the fourth conductive structure is aligned with and separated from the first conductive structure by the molding compound

16. The antenna package as claimed in claim 1, further comprising:
a second passive component module arranged side-by-side with the first passive component module, wherein the first antenna module overlaps and is electrically connected to the second passive component module, and wherein the second passive component module is electrically connected to a second antenna module arranged beside the first antenna module.

17-18. (canceled)

19. The antenna package as claimed in claim 16, wherein the first antenna module and the second antenna module are operated in different frequency bands and/or radiated directions, and wherein the first passive component module and the second antenna module comprises interconnect structures formed of different numbers of dielectric layers.

20. The antenna package as claimed in claim 1, wherein the first antenna module is fabricated without any passive component disposed therein, and the first passive component module is fabricated without any antenna disposed therein.

21. An antenna package, comprising:
a first number of passive component modules each having a first pad close to a top surface and a second pad close to a bottom surface;
a second number of antenna modules separated from the first number of passive component modules, wherein each of the second number of antenna modules has a third pad connected to at least one of the first pads; and
first conductive structures directly connected to the first pads and connected to the third pads; and
second conductive structures directly connected to the second pads.

22. The antenna package as claimed in claim 21, wherein each of the passive component modules comprises:
a first substrate; and
a passive component disposed in the first substrate and electrically connected to the first conductive structures and the second conductive structures, wherein each of the passive component modules is fabricated without an antenna disposed therein; and
wherein each of the antenna modules comprises:
a second substrate; and
an antenna disposed on the second substrate different from the first substrate, wherein each of the antenna modules is fabricated without any passive components disposed therein.

23. An antenna package, comprising:
a first individual passive component module having a top surface, a bottom surface and a first side surface between the top surface and the bottom surface;
a first individual antenna module stacked on the top surface of the first passive component module, wherein the first individual antenna module is operated in a first frequency band;
a second individual antenna module stacked on the top surface or the first side surface of the first individual passive component module, wherein the second individual antenna module is operated in a second frequency band;
a first conductive structure in contact with the top surface of the first individual passive component module and electrically connected to the first individual antenna module; and
a second conductive structure in contact with the bottom surface of the first passive component module.
